(19) United States
(12) Patent Application Publication
(10) Pub. No.: US 2004/0187787 A1
(43) Pub. Date: Sep. 30, 2004

(54) Substrate support having temperature controlled substrate support surface

(76) Inventors: Keith E. Dawson, Livermore, CA (US); Eric H. Lenz, Pleasanton, CA (US)

Correspondence Address: BURNS, DOANE, SWECKER & MATHIS, L.L.P., P.O. Box 1404, Alexandria, VA, 22313-1404, US

(21) Appl. No.: 10/401,861

(22) Filed: Mar. 31, 2003

(51) Int. Cl. C23C 16/00

(52) U.S. Cl. 118/728

(57) ABSTRACT

A substrate support having a temperature controlled substrate support surface includes a liquid supply system having at least one liquid source and a plurality of liquid flow passages. The liquid supply system can include valves to control the distribution of liquid to the liquid flow passages. The liquid supply system also can include a controller to control its operation. Liquid can be distributed through the liquid flow passages in various patterns. The substrate support can also include a heat transfer gas supply system, which supplies a heat transfer gas between the substrate support surface and a substrate supported on the substrate support surface.

### FIELD OF INVENTION

The invention relates to plasma processing apparatuses and, more particularly, to a temperature controlled substrate support.

### BACKGROUND OF INVENTION

Plasma processing apparatuses are used for processes including plasma etching of semiconducting, dielectric and metallic materials, physical vapor deposition, chemical vapor deposition (CVD), ion implantation and resist removal. Such substrates include, for example, semiconductor wafers and flat screen displays. The substrates can have various regular and irregular shapes and sizes.

One type of plasma processing apparatus used in semiconductor material processing includes a reaction chamber containing an upper electrode (anode) and a lower electrode (cathode). A substrate to be processed is supported in the reaction chamber on a substrate support. A process gas is introduced into the reaction chamber by a gas distribution system. An electric field established between the anode and the cathode generates a plasma from the process gas.

During plasma processing, it is desirable that material removal from the substrate by etching and material deposition on the substrate be uniform so that devices fabricated from the processed substrates have satisfactory electrical properties. However, as semiconductor wafer size has increased while the size of features formed on the wafers has decreased, it has become increasingly difficult to achieve this goal.

Substrates are secured on the substrate support in the reaction chamber during plasma processing by substrate holders including mechanical chucks and electrostatic chucks (ESCs). Systems designed to affect heat transfer in substrate supports used in plasma processing apparatuses are disclosed in U.S. Pat. Nos. 5,310,453; 5,382,311; 5,609,720; 5,671,116; 5,675,471; 5,835,344; 6,077,357; 6,108,189; 6,179,921; 6,231,776; 6,310,755; 6,373,681; 6,377,437; 6,394,797 and 6,378,600.

### SUMMARY OF INVENTION

A substrate support useful in a plasma processing apparatus is provided. The substrate support can provide temperature control at a surface of the substrate support that supports a substrate during plasma processing.

In a preferred embodiment, the substrate support comprises a body having a support surface for supporting a substrate in a reaction chamber of a plasma processing apparatus; a first liquid flow passage extending through a first portion of the body so as to provide temperature control of a first portion of the support surface; a second liquid flow passage extending through a second portion of the body so as to provide temperature control of a second portion of the support surface; a first inlet and a first outlet in fluid communication with the first liquid flow passage; and a second inlet and a second outlet in fluid communication with the second liquid flow passage.

Another preferred embodiment of the substrate support comprises a body having a support surface for supporting a substrate in a reaction chamber of a plasma processing apparatus, a plurality of liquid flow passages provided in the body, each liquid flow passage having a supply line and a return line, and a liquid supply system including at least one liquid source. The liquid supply system is operable to supply a liquid from the at least one liquid source to one or more selected liquid flow passages to produce a controlled temperature distribution across the support surface.

### BRIEF DESCRIPTION OF THE DRAWINGS

In the accompanying drawings:

FIG. 1 illustrates an exemplary plasma reaction chamber in which preferred embodiments of the substrate support can be used.

FIG. 2 is a side sectional view of a portion of a preferred embodiment of a substrate support.

FIG. 3 is a bottom plan view of a surface of a preferred embodiment of the substrate support including radially distributed liquid flow passages and thermal breaks.

FIG. 4 is a bottom plan view of a surface of another preferred embodiment of the substrate support, having another distribution of liquid flow passages and thermal breaks.

FIG. 5 schematically illustrates a preferred embodiment of the substrate support including a liquid supply system and a heat transfer gas supply system.

FIG. 6 schematically illustrates a preferred embodiment of the liquid supply system.

FIG. 7 schematically illustrates another preferred embodiment of the liquid supply system.

### DETAILED DESCRIPTION OF PREFERRED EMBODIMENTS

In order to enhance the uniformity of plasma processing of a substrate in a plasma processing apparatus, it is desirable to control the temperature distribution at an exposed surface of the substrate where material deposition and/or etching occurs. In plasma etching processes, variations in the substrate temperature and/or in rates of chemical reaction at the substrate's exposed surface can cause undesirable variations in the etching rate of the substrate, as well as in etch selectivity and anisotropy. In material deposition processes, such as CVD processes, the deposition rate and the composition and properties of material deposited on the substrate can be significantly affected by the temperature of the substrate during deposition.

Backside gas cooling systems have been used in substrate supports to provide heat transfer between the substrate support and substrates supported on the substrate support. However, it has been determined that the heat transfer effects of heat transfer gases, such as helium, are dependent on the surface conditions of the substrate support, and such conditions may change during processing. Consequently, the ability of the heat transfer gas to remove heat may be diminished during processing.

Substrate supports have included coolant flow passages to remove heat from the substrate support during processing. In such cooling systems, coolant at a controlled temperature and a set volumetric flow rate is introduced into the coolant flow passages. Substrate supports have included one supply line and one return line in the cooling system. However, it has been determined that as heat is removed from the substrate support, a significant temperature gradient can develop along the length of the passages, from the inlet to the outlet. As a result, the temperature uniformity at the surface of the substrate support in contact with the heat transfer gas and the substrate is not controlled. Substrate holders also provide a heat sink at the back side of the substrate. Resulting heat transfer from the substrate to the substrate holder has contributed to non-uniformity of temperature across the substrate in known plasma processing apparatuses.

In light of these shortcomings, a temperature controlled substrate support for use in a plasma processing apparatus is provided. In a preferred embodiment, the substrate support provides temperature control across a surface of the substrate support. The substrate support comprises a liquid supply system including a plurality of liquid flow passages. Desired temperature control of the surface of the substrate support can be achieved by controlling the distribution of liquid to the liquid flow passages. In addition, parameters of the liquid, such as the temperature and/or flow rate of the liquid through liquid flow passages, can preferably be controlled.

In a preferred embodiment, the temperature at a given location of the substrate support is related to the respective temperatures of the liquid flow passages. By reducing and/or eliminating liquid flow in one or more liquid flow passages at one or more portions of the substrate support, the portion(s) can be caused to become hotter than other portions of the substrate support located near liquid flow passages that have a higher rate of liquid flow through them.

In a preferred embodiment, the liquid supply system of the substrate support includes one or more valves. Operation of the valve(s) can be controlled to distribute liquid to one or more liquid flow passages, to prevent liquid flow through one or more liquid flow passages, and/or to divert liquid between one or more liquid flow passages.

In a preferred embodiment, the substrate support includes a heat transfer gas supply system, which is operable to supply heat transfer gas between a surface of the substrate support and the substrate, such as a semiconductor wafer, supported on the surface. By incorporation of the liquid supply system in the substrate support, temperature conditions at the surface of the substrate support can be controlled, and heat transfer gas can be supplied to control heat transfer between the substrate and substrate support during processing. Thus, enhanced control of the wafer temperature can be achieved using the substrate support.

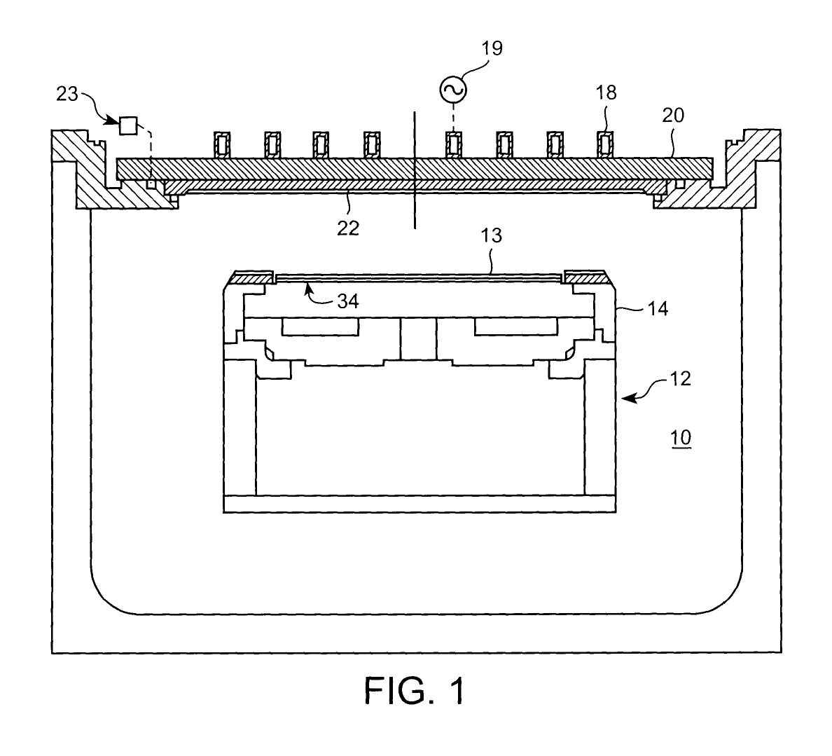

An exemplary plasma reactor in which preferred embodiments of the substrate support can be used is illustrated in FIG. 1. The plasma reactor is an inductively coupled plasma reactor. It will be appreciated by those having ordinary skill in the art that the substrate support can be used in other types of plasma reactors in which temperature control of a substrate during plasma processing is desired, such as other inductively coupled plasma reactor constructions, ECR, magnetron, and capacitively coupled plasma reactors. The plasma reactor shown in FIG. 1 comprises a reaction chamber 10 including a substrate holder 12 with an electrostatic chuck 34, which provides a clamping force to a substrate 13, as well as an RF bias to the substrate. The substrate 13 can be, for example, a semiconductor wafer. A focus ring 14 enhances plasma above the substrate 13. An energy source is disposed at the top of reaction chamber 10 for generating a plasma in the reaction chamber. The energy source can be, for example, an antenna 18 powered by an RF source to generate plasma. The reaction chamber 10 includes vacuum pumping apparatus for maintaining the interior of the chamber at a desired pressure.

A dielectric window 20 is disposed between the antenna 18 and the interior of the processing chamber 10 and forms a wall of the reaction chamber 10. A gas distribution plate 22 is beneath the window 20 and includes openings through which process gas is delivered from a gas supply 23 to the reaction chamber 10.

In operation, the substrate 13 is placed on an exposed surface of the substrate holder 12 and held in place by the electrostatic chuck 34. As described below, heat transfer gas is preferably employed to improve heat transfer between the substrate 13 and the electrostatic chuck 34. Process gas is supplied to the reaction chamber 10 through a gap between the window 20 and the gas distribution plate 22. A plasma is generated in the space between the substrate 13 and the window 20 by supplying RF power to the antenna 18.

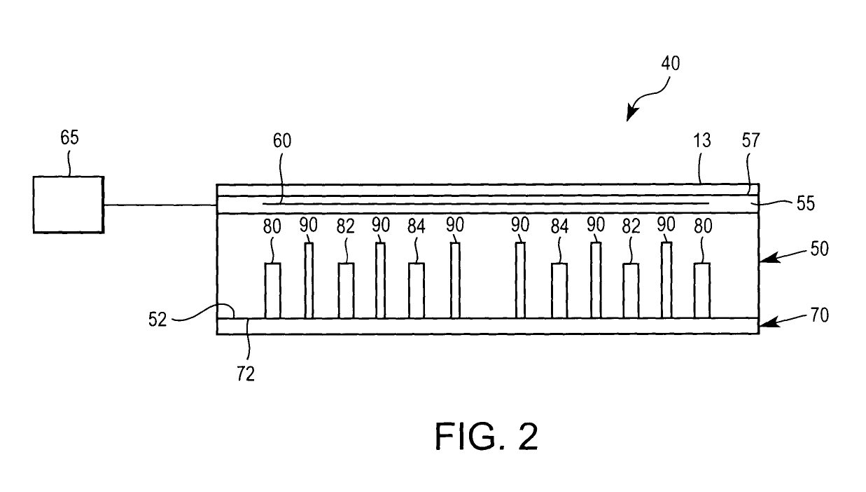

FIG. 2 illustrates a portion of a preferred embodiment of a substrate support 40, which includes an electrostatic chuck. The substrate support 40 comprises a body 50, a dielectric layer 55, an electrically conductive electrode 60 embedded in the dielectric layer 55, a power source 65 electrically connected to the conductive material 60, and a cover 70. The power source 65 applies DC bias to the electrode 60. The dielectric layer 55 includes an exposed surface 57 on which the substrate 13 is supported. The exposed surface 57 is preferably circular. The cover 70 includes a surface 72 facing a surface 52 of the body 50.

The substrate support 40 can alternatively include a different type of chuck, such as a mechanical chuck. Mechanical chucks include a mechanical clamping arrangement, such as a clamping ring, for securing a substrate on the chuck during processing.

The substrate support 40 preferably includes a plurality of liquid flow passages, such as liquid flow passages 80, 82 and 84. As described in greater detail below, liquid can be circulated through the liquid flow passages in a controlled manner to control the temperature distribution at the exposed surface 57.

The substrate support 40 preferably also includes one or more thermal breaks 90. As described in greater detail below, the thermal breaks 90 reduce heat transfer at one or more portions of the body 50. The liquid supply system and the thermal breaks provide controlled heat transfer capabilities in the substrate support 40, thereby providing enhanced control of the temperature of the substrate 13.

The body 50 of the substrate support 40 can comprise a suitable metal or metal alloy, such as aluminum, aluminum alloys, or the like.

The dielectric layer 55 can comprise a suitable ceramic material, such as alumina, or the like. The conductive material 60 can be tungsten, or the like.

The cover 70 can comprise a suitable metal or metal alloy, such as aluminum or aluminum alloys.

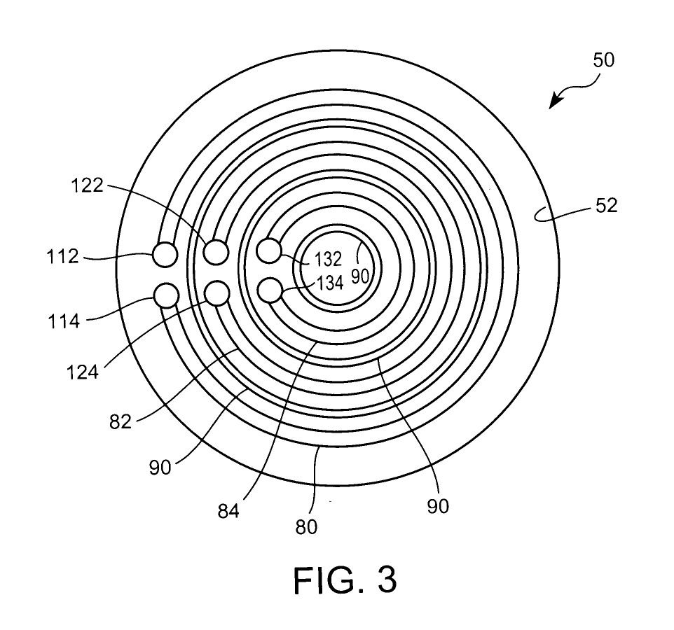

FIG. 3 shows a preferred configuration of a substrate support 40 used for wafer processing, which includes an arrangement of annular liquid flow passages 80, 82 and 84. The liquid flow passages 80, 82 and 84 preferably comprise channels formed in the surface 52 of the body 50. The liquid flow passages 80, 82 and 84 are preferably parallel to the exposed surface 57.

The surface 72 of the cover 70 abuts the surface 52 of the body 50 and thereby partially defines the liquid flow passages 80, 82 and 84. The cover 70 can be removably attached to the body 50 by fasteners or the like, or alternatively permanently attached to the body by welding, brazing or the like.

The liquid flow passages in the substrate support 40 can have various cross-sectional shapes, including, for example, semi-circular, circular, rectangular, square, other polygonal shapes and the like. The cross-sectional area (i.e., transverse cross-sectional area) of the liquid flow passages can be chosen to provide a desired volume of the liquid flow passages based on various considerations including, for example, the desired volumetric flow rate of the liquid through the liquid flow passages and the heat transfer capabilities of the liquid. For example, to increase heat transfer by the liquid, the volumetric flow rate of the liquid through the liquid flow passages can be increased, or a liquid having increased heat transfer capabilities can be used.

The liquid flow passages in the substrate support 40 can all have the same cross-sectional area, or two or more liquid flow passages can have different cross-sectional areas. For example, in one or more portions of the body 50 where relatively greater heat transfer is desired, the liquid flow passage cross-sectional area can be greater than in other portions where less heat transfer is desired.

The liquid flow passages 80, 82 and 84 are preferably concentrically arranged in the surface 52 of the body 50, such as in the preferred embodiment shown in FIG. 3. Such concentric arrangement of the liquid flow passages can provide control of the radial temperature distribution across the exposed surface 57.

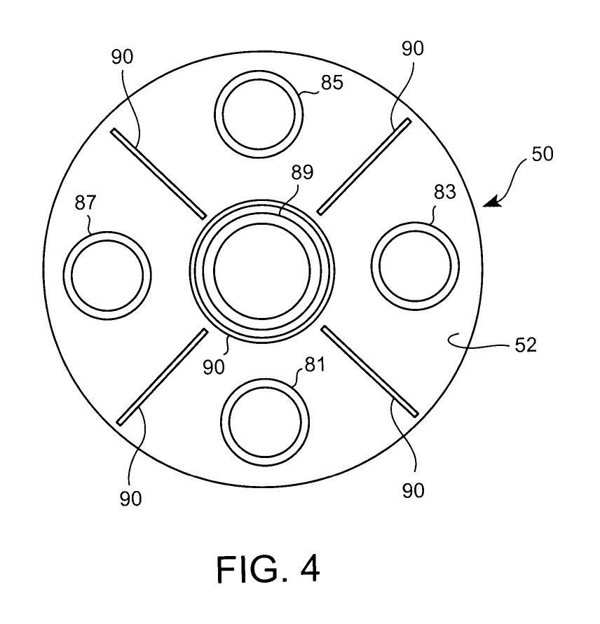

The liquid flow passages can alternatively have other arrangements in the substrate support 40 to provide other controlled spatial temperature distributions at the exposed surface 57. For example, FIG. 4 illustrates a non-concentric arrangement of radially offset and circumferentially spaced apart liquid flow passages 81, 83, 85, 87 and centrally located passage 89. A thermal break 90 surrounds the central liquid flow passage 89. Radially extending thermal breaks 90 are provided between the liquid flow passages 81, 83, 85 and 87, to physically and thermally isolate liquid flow passages from other liquid flow passages and/or portions of the substrate support 40. The liquid flow passages 81, 83, 85, 87 and 89 are preferably annular. However, the liquid flow passages can have other configurations, such as rectangular, oval or the like. The liquid flow passages 81, 83, 85, 87 and 89 are preferably parallel to the exposed surface 57. However, the liquid flow passages can have other orientations.

The liquid flow passages in the substrate support 40 can be formed by any suitable process. For example, the liquid flow passages can be formed in the surface 52 of the body 50 by machining, or alternatively by a process used to make the body, such as a casting process.

The liquid can be any liquid having suitable heat transfer properties for use in the substrate support 40. For example, the liquid can be water (e.g., deionized water), ethylene glycol, silicon oil, water/ethylene glycol mixtures, and the like. The cooling performance of the liquid can be controlled by using different liquids and/or mixtures of different liquids, varying the liquid flow rate, and/or varying the initial temperature of the liquid (i.e., the temperature of the liquid introduced into one or more liquid flow passages). The temperature of the liquid can preferably be adjusted by the liquid supply system, as described below.

The thermal breaks 90 control heat transfer in the substrate support 40. For example, in the preferred embodiment shown in FIG. 2, thermal breaks 90 are located between adjacent liquid flow passages 80, 82 and 82, 84, and a thermal break 90 is surrounded by liquid flow passage 84. The thermal breaks 90 reduce heat transfer through the body 50 in the portions between the liquid flow passages 80, 82 and 82, 84, and in the portion inside of liquid flow passage 84, by physically and thermally isolating the liquid flow passages from each other. In the preferred embodiment shown in FIG. 4, the thermal breaks 90 control heat transfer between the liquid flow passages 81, 83, 85, 87 and 89. By reducing heat transfer between the liquid flow passages, heat transfer effects (i.e., heating and/or cooling) of liquid flow passages on each other are reduced, thereby enhancing thermal control of the liquid flow passages and surrounding portions of the body.

Thermal breaks can also, or alternatively, be provided above and/or below the liquid flow passages 80, 82 and 84 (or liquid flow passages 81, 83, 85, 87 89), and/or at other locations of the body 50 of the substrate support 40. For example, one or more thermal breaks can be disposed radially outward from the liquid flow passage 80 to control heat transfer in this portion. The thermal breaks reduce heat conduction through the body 50 in portions between liquid flow passages and/or in other portions of the substrate support 40.

The thermal breaks 90 can comprise various suitable materials having reduced thermal conductivity. For example, the thermal breaks 90 can comprise suitable fluids having low thermal conductivity, including gases, such as air, and liquids. The thermal breaks 90 can alternatively comprise suitable solid materials having low thermal conductivity, including metals and other materials, such as stainless steels, and thermal insulators, such as suitable ceramic materials and polymers.

The thermal breaks 90 can have different configurations in the substrate support 40. As depicted in FIGS. 1 and 2, the thermal breaks 90 preferably comprise annular channels located between adjacent liquid flow passages, proximate liquid flow passages, and/or above and/or below liquid flow passages. The thermal breaks can be voids between liquid flow passages, such as portions exposed to atmospheric air.

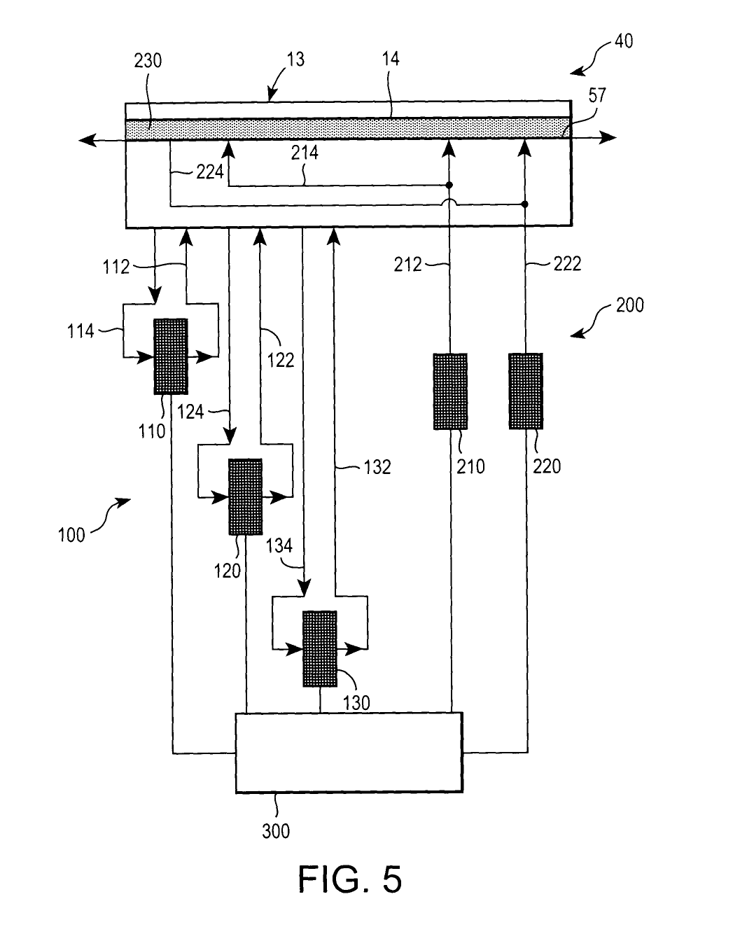

FIG. 5 illustrates a preferred embodiment of the substrate support 40 including a liquid supply system 100, a heat transfer gas supply system 200 and a controller 300. The liquid supply system 100 includes one or more liquid sources for supplying liquid to the liquid flow passages. The liquid supply system preferably includes a plurality of liquid sources, such as the liquid sources 110, 120 and 130. The liquid sources 110, 120 and 130 can comprise chillers, heat exchangers, and the like, which are operable to supply liquid, preferably at a selected temperature and/or flow rate, to the respective liquid flow passages 80, 82 and 84 (FIG. 3), or 81, 83, 85, 87, 89 (FIG. 4). The liquid supply system 100 can also comprise a suitable fluid pump arrangement.

In the embodiment shown in FIGS. 2 and 3, the liquid flow passages 80, 82 and 84 include supply lines 112, 122 and 132, respectively, and return lines 114, 124 and 134, respectively, in fluid communication with the liquid sources 110, 120 and 130, respectively. Liquid is supplied from the liquid sources 110, 120 and 130 to the liquid flow passages 80, 82 and 84, respectively, via the supply lines 112, 122 and 132, the liquid is circulated through the liquid flow passages 80, 82 and 84, and the liquid is returned to the liquid sources 110, 120 and 130, respectively, via the return lines 114, 124 and 134, respectively.

The heat transfer gas supply system 200 includes one or more heat transfer gas sources, such as heat transfer gas sources 210 and 220. The heat transfer gas sources 210, 220 supply heat transfer gas to the heat transfer gas passages 212, 214 and 222, 224, respectively. Heat transfer gas is flowed through the heat transfer gas passages 212, 214 and 222, 224 to the exposed surface 57, where the heat transfer gas is distributed via openings and/or channels (not shown) formed in the exposed surface 57 to the interface portion 230 (shown enlarged in FIG. 5) between the exposed surface 57 and the backside 14 of the substrate 13. A suitable heat transfer gas supply system, which provides zone cooling of the exposed surface of a substrate support, is disclosed in commonly-assigned U.S. Pat. No. 5,609,720, which is incorporated herein by reference in its entirety.

The heat transfer gas can be any gas having heat transfer capabilities to sufficiently transfer heat away from the substrate 13 during plasma processing. For example, the heat transfer gas can be helium, or the like.

The liquid sources 110, 120 and 130 and the heat transfer gas sources 210 and 220 are preferably controlled by the controller 300. The controller 300 can control operation of the liquid sources 110, 120 and 130 to selectively vary parameters of the liquid supplied to the liquid flow passages 80, 82 and 84, and also control operation of the heat transfer gas sources 210 and 220 to selectively vary parameters of the heat transfer gas supplied to the heat transfer gas passages 212, 214 and 222, 224. As described in greater detail below, the controller 300 preferably can control operation of the liquid sources 110, 120, 130 to control the distribution, temperature and/or flow rate of liquid supplied to the liquid flow passages by the liquid sources, and preferably can control operation of the heat transfer gas sources 210 and 220 to control the flow rate of heat transfer gas supplied to the interface portion 230, to achieve a desired temperature distribution across the exposed surface 57.

The controller 300 preferably receives signals from one or more temperature sensors (not shown) disposed to measure temperature at one or more selected locations of the substrate support 40 and/or on the substrate 13 (e.g., at the backside 14). For example, temperature sensors can be disposed to measure temperature within the body 50 at locations proximate one or more liquid flow passages, in the peripheral portion of the substrate support 40, and/or at locations proximate the exposed surface 57. The temperature sensors preferably provide real time temperature measurements to enable feedback control of the operation of the liquid sources 110, 120 and 130 and associated valves described below, as well as control of the operation of the heat transfer gas sources 210 and 220. The controller 300 can be manually operable or programmed to automatically control operation of the liquid sources 110, 120 and 130, the heat transfer gas sources 210 and 220, and associated valves, as described below.

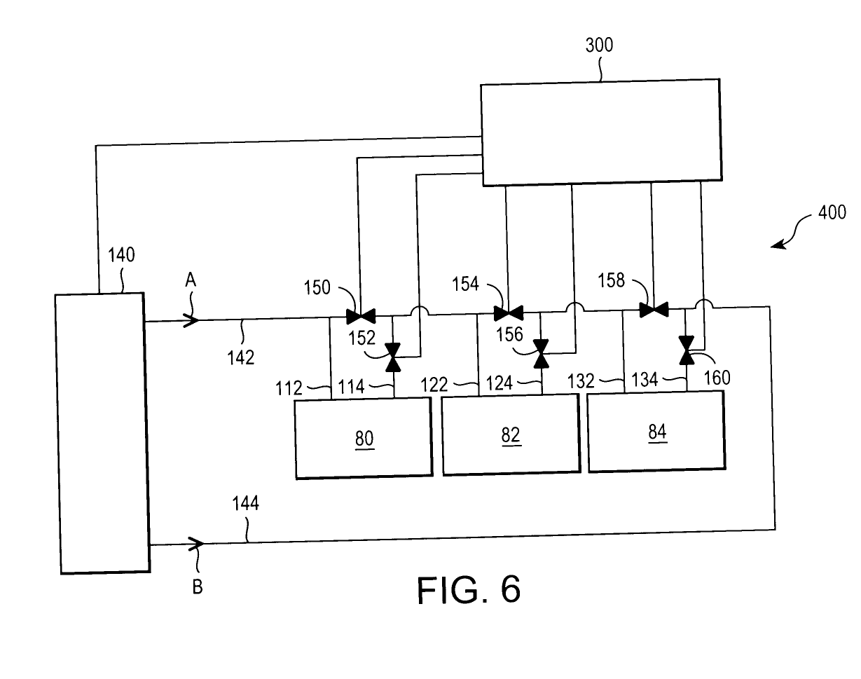

FIG. 6 illustrates another preferred embodiment of the liquid supply system 400 of the substrate support. The liquid supply system 400 includes a liquid source 140, such as a chiller, heat exchanger, or the like, and a supply line 142 and return line 144, which provide fluid communication to and from the liquid flow passages 80, 82 and 84 (or liquid flow passages 81, 83, 85, 87, 89). The liquid source 140 can alternatively comprise a plurality of sources, such as a separate chiller, heat exchanger, or the like operatively associated with each respective liquid flow passage 80, 82 and 84 (or liquid flow passages 81, 83, 85, 87, 89). The liquid supply system 400 can also comprise a suitable fluid pump arrangement.

One or more valves preferably are operatively associated with the liquid flow passages 80, 82 and 84 (or liquid flow passages 81, 83, 85, 87, 89) to provide control of the distribution of the liquid to and from the liquid flow passages in the liquid supply system 400. For example, valves 150 and 152 preferably are operatively associated with the liquid flow passage 80, valves 154 and 156 preferably are operatively associated with the liquid flow passage 82, and valves 158 and 160 preferably are operatively associated with the liquid flow passage 84.

The valves 152, 156 and 160 are preferably operable to provide various flow patterns of liquid through the liquid flow passages 80, 82 and 84. The valves 152, 156 and 160 and the liquid source 140 are preferably controlled by the controller 300. In a preferred embodiment, liquid is sequentially distributed in the direction A through the coolant flow passages 80, 82 and 84. For example, the valves 152, 156 and 160 can be operated to sequentially flow liquid through the liquid flow passages 80, 82 and 84 in this order. To achieve such sequential flow, liquid is distributed from the liquid source 140 first to the liquid flow passage 80 via supply line 142 and supply line 112, with the valves 156 and 160 closed. To next distribute liquid to the liquid flow passage 82, valve 156 is opened with the valve 160 closed.

If it is not desired to flow liquid simultaneously through liquid flow passages 80 and 82, valve 152 can be closed to terminate flow through the liquid flow passage 80. If it is desired to continue flow of liquid through the liquid flow passage 80, but at a reduced flow rate, as liquid is also flowed through liquid flow passage 82, valve 152 can be partially closed to reduce flow through the liquid flow passage 80. To then distribute liquid to the liquid flow passage 84, valve 160 is opened. If it is not desired to simultaneously flow liquid through the liquid flow passage 80 and/or liquid flow passage 82 and the liquid flow passage 84, valve 152 and/or valve 156 can be closed to terminate flow. through the liquid flow passage 80 and/or liquid flow passage 82. If it is desired to continue flow of liquid through the liquid flow passage 80 and/or the liquid flow passage 82, but at a reduced flow rate, simultaneously with liquid flow through liquid flow passage 84, valve 152 and/or valve 156 can be partially closed to reduce flow through the liquid flow passage 80 and/or liquid flow passage 82.

In another preferred embodiment, one or more of the coolant flow passages 80, 82 and 84 (or liquid flow passages 81, 83, 85, 87, 89) can be bypassed by liquid to increase volumetric flow of the liquid to one or more non-bypassed liquid flow passages. Such embodiments enable temperature adjustment at selected portions of the substrate support 40 to achieve and/or maintain a desired temperature distribution across the exposed surface 57. Liquid is distributed from the liquid source 140 to one or two of the liquid flow passages 80, 82 and 84 via supply line 142. For example, liquid can be distributed to liquid flow passage 80 and then be distributed to only one of the liquid flow passages 82, 84, or alternatively can be returned to the liquid source 140 via return line 144, by opening and/or closing the valves 156 and 160. For example, if liquid flow through liquid flow passage 84 is desired, but not also through liquid flow passage 82, valve 156 can be closed, with valve 160 being opened. If it is desired to bypass both liquid flow passages 82, 84 and return liquid from liquid flow passage 80 directly to the liquid source 140 via return line 144, valves 156 and 160 can both be closed, with valves 154 and 158 being opened.

In another preferred embodiment, the liquid coolant supply system 400 can be operated to distribute liquid in the reverse direction B from the return line 144 to the supply line 142. For example, if it desired to sequentially distribute liquid to the liquid flow passages 84, 82 and 80 in this order, or to bypass any of the liquid flow passages 80, 82 and 84, the liquid can be flowed in direction B and the valves 152, 156 and 160 can be operated to achieve the desired liquid distribution.

The liquid supply system 400 (as well as other embodiments of the liquid supply system described herein) is preferably operable to vary the amount of time that liquid is flowed through the liquid flow passages 80, 82 and 84 (or liquid flow passages 81, 83, 85, 87, 89). For example, liquid can be flowed through liquid flow passage 84 for longer than through liquid flow passage 80 and/or liquid flow passage 82 in order to enhance cooling in the portion of the body 50 affected by liquid flow passage 84.

In addition, the liquid supply system 400 (as well as other embodiments of the liquid supply system described herein) is preferably operable to provide different flow rates of the liquid through the respective liquid flow passages 80, 82 and 84 (or liquid flow passages 81, 83, 85, 87, 89). For example, to increase the flow rate of liquid through the liquid flow passage 84, valve 152 and/or valve 156 can be partially or fully closed to reduce or terminate liquid flow through liquid flow passage 80 and/or liquid flow passage 82. The flow rate of the liquid supplied by the liquid source 140 can also be increased with valve 152 and/or valve 156 in the partially or fully closed position. Reducing and/or eliminating liquid flow through one or more liquid flow passages causes heating of the portions of the body 50 that are affected by those liquid flow passages, while heat removal from those portions of the body 50 that are affected by liquid flow passages having increased liquid flow is increased.

In addition, the temperature of liquid distributed to the liquid flow passages 80, 82 and 84 (or liquid flow passages 81, 83, 85, 87, 89) can preferably be controlled. For example, liquid preferably can be supplied at about the same temperature from the liquid source 140 to each of the liquid flow passages 80, 82 and 84. Alternatively, liquid preferably can be supplied at a different temperature to at least one of the liquid flow passages 80, 82 and 84. For example, liquid having a first temperature can be supplied to the liquid flow passage 84 while liquid having a higher or lower second temperature can be supplied to the liquid flow passages 80 and 82. Alternatively, liquid having three different temperatures can be distributed to the respective liquid flow passages 80, 82 and 84.

The number of liquid flow passages in the substrate support 40 can be varied to control cooling. For example, the substrate support 40 can include three liquid flow passages, such as in the embodiment shown in FIG. 6, as well as other numbers of coolant flow passages, such as two, four, five (e.g., FIG. 5) or more. For example, in the substrate support 40 shown in FIG. 6, the number of liquid flow passages can be reduced to two by eliminating intermediate liquid flow passage 82. Alternatively, a fourth liquid flow passage (not shown) can be provided radially outward from the liquid flow passage 84 to provide control of the temperature at the peripheral portion of the body 50.

The valves 150, 152, 154, 156, and 160 are preferably two-way valves. However, other types of valves, such as one-way valves, three-wave valves and/or other suitable valves, may alternatively be used in the liquid supply system 400 (and in other embodiments of the liquid supply system described herein). For example, if reverse flow capabilities are not desired, valves 150, 152, 154, 156, 158 and 160 can be one-way valves. Alternatively, one or more three-way valves can be used to reduce the number of valves in the liquid supply system 400 and in other embodiments of the liquid supply system described herein. The valves are preferably operable to control the fluid flow rate through the valves.

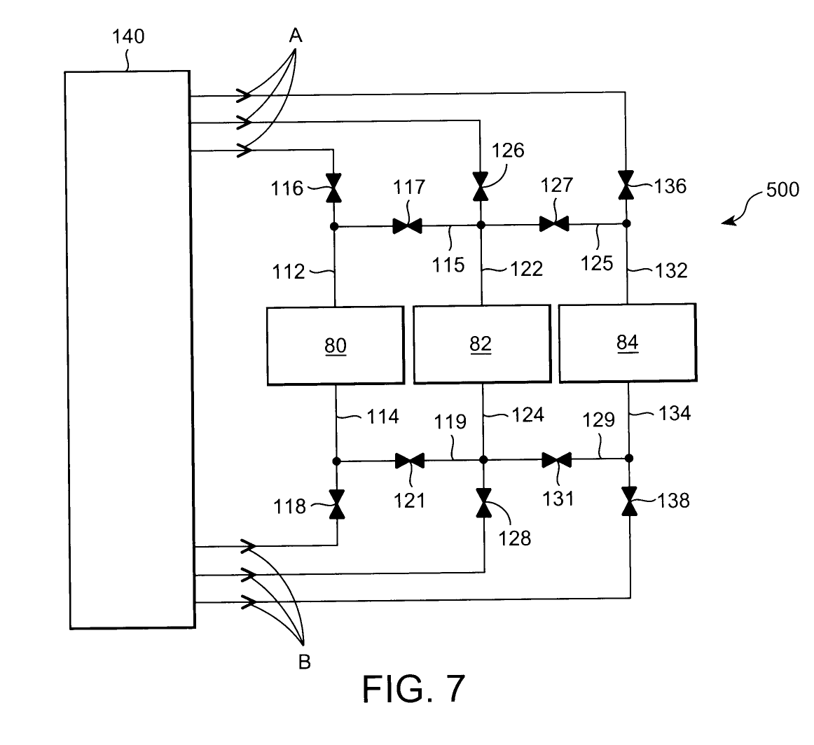

FIG. 7 illustrates another preferred embodiment of the liquid supply system 500 including a liquid source 140 and coolant flow passages 80, 82 and 84. The liquid source 140 can comprise a single chiller, heat exchanger, or the like, or it can be comprise a plurality of liquid sources. For example, the liquid source 140 can comprise a liquid source operatively associated with each respective liquid flow passage 80, 82 and 84. Alternatively, each liquid source can be operatively associated with two or more of liquid flow passages 80, 82, and 84, as described below. The coolant supply system 500 preferably also includes a controller (not shown) for controlling its operation. The liquid supply system 500 can also comprise a suitable fluid pump arrangement.

The liquid flow passages 80, 82 and 84 have an associated supply line 112, 122 and 132, respectively, and an associated return line 114, 124 and 134, respectively. Valves 116, 126 and 136 preferably are provided in supply lines 112, 122 and 132, respectively, and valves 114, 124 and 134 preferably are provided in return lines 114, 124 and 134, respectively. Bypasses 115 and 125 provide fluid communication between supply lines 112, 122 and 122, 132, respectively, and bypasses 119 and 129 provide fluid communication between return lines 114, 124 and 124, 134, respectively.

The liquid supply system 500 preferably is operable to provide different flow patterns of the liquid through the liquid flow passages 80, 82 and 84. For example, liquid can be distributed to only one, only two, or to all three, liquid flow passages 80, 82, 84, by selective operation of the valves. For example, to distribute liquid only to liquid flow passage 80, valves 117, 121, 126 and 136 can be closed, with valves 116 and 118 being opened.

To distribute liquid to liquid flow passage 82 only, the valves can be configured in various alternative configurations. For example, all valves except valves 126 and 128 can be closed. Alternatively, valves 116, 117, 126, 128, 127 and 136 can be opened, with valves 118, 121, 131 and 138 closed. In such arrangement, the rate of flow of liquid through liquid flow passage 82 can be enhanced by the liquid distributed to liquid flow passage 82 from supply lines 112 and 132. Valves 116 and 117 or valves 127, 136 can alternatively be closed to prevent distribution of the liquid from the supply line 112 or 132 to the supply line 122 associated with the liquid flow passage 82.

To distribute liquid to liquid flow passages 80 and 82 without distributing liquid to liquid flow passage 84, the valves can be configured in various alternative configurations. For example, valves 116, 117, 126, 118, 121 and 128 can be opened with valves 127, 131, 136 and 138 being closed. In such arrangement, liquid can be distributed via bypasses 115 and 119. Alternatively, the valves 116, 126, 118 can be opened, with valves 127, 131, 136 and 138, and additionally valves 117 and 121, being closed. In such arrangement, liquid is not distributed through bypasses 115 and 119.

To distribute liquid to each of the liquid flow passages 80, 82 and 84, the valves can be configured in various alternative configurations. For example, all valves can be opened such that liquid is distributed via bypasses 117, 121, 127 and 131. Alternatively, one or more of valves 117, 121, 127 and 131 can be closed to prevent liquid flow through one or more of bypasses 115, 119, 125 and 129, respectively.

Liquid can be distributed to the liquid flow passages 80, 82 and 84 in various temporal flow patterns. For example, liquid can be sequentially distributed to liquid flow passages 80, 82 and 84 in this order, to liquid flow passages 84, 82 and 80 in this order, to liquid flow passages 80, 84 and 82 in this order, or to liquid flow passages 84, 80 and 82 in this order.

The direction of liquid flow in the liquid supply system 500 shown in FIG. 7 can alternatively be reversed from direction A to direction B, so that one or more return lines 114, 124 and 134 act as a supply line, while one or more supply lines 112, 122 and 132 act as a return line.

The liquid supply system 500 shown in shown in FIG. 7 is preferably operable to control the amount of time that the liquid is flowed through the liquid flow passages 80, 82 and 84. In addition, the liquid supply system 500 is preferably operable to provide different flow rates of the liquid through the respective liquid flow passages 80, 82 and 84. Furthermore, the temperature of liquid distributed to the liquid flow passages 80, 82 and 84 is preferably controllable. For example, liquid preferably can be supplied at about the same temperature from the liquid source 140 to each of the liquid flow passages 80, 82 and 84. Alternatively, the liquid can be supplied at a different temperature to at least one of the liquid flow passages 80, 82 and 84.

Preferably, the controller is operable to control operation of the liquid source 140 and the valves 116, 117, 118, 121, 126, 127, 128, 131, 136 and 138, to control liquid flow through the liquid flow passages 80, 82 and 84, thereby controlling the temperature distribution at the exposed surface 57 of the substrate support 40. The controller preferably also is operable to control the distribution of heat transfer gas between the exposed surface of the substrate support and the backside of substrates supported on the exposed surface.

Accordingly, by providing control of liquid distribution to a plurality of liquid flow passages, the substrate support 40 can provide improved temperature control of substrates supported on the substrate support. The substrate support preferably also provides controlled distribution of heat transfer gas. The substrate support can provide substrate temperature profiles according to different process needs. For example, the substrate support can provide a uniform, or non-uniform, radial temperature distribution across a substrate, or it can alternatively provide other desired uniform, or non-uniform, temperature distributions.

The substrate support can be used in a plasma processing apparatus in which various plasma processing operations including plasma etching, physical vapor deposition, chemical vapor deposition (CVD), ion implantation and resist removal are performed. The plasma processing operations can be performed for various substrate materials including semiconducting, dielectric and metallic materials. The substrate support can provide improved temperature control of the substrates during such plasma processing operations. In addition, the substrate support can be used in various types of plasma processing apparatuses.

While the invention has been described in detail with reference to specific embodiments thereof, it will be apparent to those skilled in the art that various changes and modifications can be made, and equivalents employed, without departing from the scope of the appended claims.

What is claimed is:

1. A substrate support useful in a plasma processing apparatus, comprising:
a body having a support surface for supporting a substrate in a reaction chamber of a plasma processing apparatus;
a first liquid flow passage extending through a first portion of the body so as to provide temperature control of a first portion of the support surface;
a second liquid flow passage extending through a second portion of the body so as to provide temperature control of a second portion of the support surface;
a first inlet in fluid communication with the first liquid flow passage;
a second inlet in fluid communication with the second liquid flow passage;
a first outlet in fluid communication with the first liquid flow passage; and
a second outlet in fluid communication with the second liquid flow passage.

2. The substrate support of claim 1, further comprising:
a first supply line in fluid communication with the first inlet;
a second supply line in fluid communication with the second inlet;
a first return line in fluid communication with the first outlet; and
a second return line in fluid communication with the second outlet.

3. The substrate support of claim 2, further comprising:
a source of temperature controlled liquid in fluid communication with the first supply line and the second supply line;
a first valve operable to control flow of the liquid through the first supply line; and
a second valve operable to control flow of the liquid through the second supply line.

4. The substrate support of claim 3, further comprising:
a third valve operable to control flow of the liquid through the first return line; and
a fourth valve operable to control flow of the liquid through the second return line.

5. The substrate support of claim 1, further comprising:
a first source of temperature controlled liquid in fluid communication with the first supply line;
a first valve operable to control flow of the liquid through the first supply line;
a second source of temperature controlled liquid in fluid communication with the second supply line; and
a second valve operable to control flow of the liquid through the second supply line.

6. The substrate support of claim 3, further comprising a controller operable to selectively open and close the first valve and the second valve.

7. The substrate support of claim 5, further comprising a controller operable to selectively open and close the first valve and the second valve.

8. The substrate support of claim 1, wherein the support surface is circular, the first liquid flow passage is parallel to the support surface and extends in a circumferential direction, and the second liquid flow passage is parallel to the support surface and extends in a circumferential direction, the second liquid flow passage being concentric with the first liquid flow passage.

9. The substrate support of claim 1, wherein the support surface is circular, the first liquid flow passage is parallel to the support surface and extends in a circumferential direction, and the second liquid flow passage is parallel to the support surface and extends in a circumferential direction, the second liquid flow passage being non-concentric with the first liquid flow passage.

10. The substrate support of claim 1, wherein the support surface comprises an exposed surface of an electrostatic chuck.

11. The substrate support of claim 1, wherein the support body includes a thermal break between the first liquid flow passage and second liquid flow passage.

12. The substrate support of claim 11, wherein the thermal break comprises an open channel extending into the body.

13. The substrate support of claim 1, further comprising:
a third liquid flow passage extending through a third portion of the body so as to provide temperature control of a third portion of the support surface; and
a third inlet in fluid communication with the third liquid flow passage.

14. The substrate support of claim 13, wherein the support body includes a first thermal break between the first liquid flow passage and second liquid flow passage, and a second thermal break between the second liquid flow passage and the third liquid flow passage.

15. The substrate support of claim 1, further comprising at least one gas passage opening on the support surface, and a gas supply inlet through which heat transfer gas can be supplied to the gas passage.

16. The substrate support of claim 2, further comprising:
a source of temperature controlled liquid;
a first valve;
a second valve;
a third valve;
a fourth valve; and
a common line in fluid communication with the first supply line, second supply line, first return line and second return line;
wherein the common line (i) supplies liquid from the source of temperature controlled liquid to the first supply line and second supply line and (ii) receives liquid from the first return line and second return line;
wherein the first valve controls flow of the liquid through the first return line;
wherein the second valve controls flow of the liquid through the second return line;
wherein the third valve controls flow of the liquid through a portion of the common line between the first supply line and first return line; and
wherein the fourth valve controls flow of the liquid through a portion of the common line between the second supply line and second return line.

17. The substrate support of claim 1, further comprising:
a source of temperature controlled liquid;
a first valve;
a second valve;
a third valve
a fourth valve;
a fifth valve;
a sixth valve;
a first connecting line and a second connecting line in fluid communication with the first supply line, first return line, second supply line and second return line;
wherein the first supply line and the second supply line supply liquid from the source of temperature controlled liquid to the first liquid flow passage and the second liquid flow passage, respectively;
wherein the first connecting line extends between the first supply line and the second supply line;
wherein the second connecting line extends between the first return line and the second return line;
wherein the first valve controls flow of the liquid through the first supply line;
wherein the second valve controls flow of the liquid through the second supply line;
wherein the third valve controls flow of the liquid through the first connecting line;
wherein the fourth valve controls flow of the liquid through the first return line;
wherein the fifth valve controls flow of the liquid through the second return line; and
wherein the sixth valve controls flow of the liquid through the second connecting line.

18. A plasma processing apparatus comprising the substrate support according to claim 1.

19. A method of thermally controlling a substrate support in a plasma processing apparatus, comprising:
placing a substrate on the support surface of the substrate support according to claim 1 in a reaction chamber of a plasma processing apparatus;
introducing a process gas into the reaction chamber;
generating a plasma from the process gas in the reaction chamber;
processing the substrate; and
selectively distributing liquid from at least one liquid source to at least the first liquid flow passage via the first inlet and/or the second liquid flow passage via the second inlet so as to control the temperature at the first portion and/or the second portion of the support surface.

20. A substrate support useful for a plasma processing apparatus, comprising:
a body having a support surface for supporting a substrate in a reaction chamber of a plasma processing apparatus;
a plurality of liquid flow passages provided in the body, each liquid flow passage having a supply line and a return line; and
a liquid supply system including at least one liquid source in fluid communication with the supply line and the return line of the liquid flow passages, the liquid supply system being operable to supply a liquid from the at least one liquid source to one or more selected liquid flow passages to control the temperature at one or more selected portions of the support surface.

21. The substrate support of claim 20, further comprising a controller operable to control operation of the liquid supply system so as to:
(i) sequentially distribute the liquid from the at least one liquid source to two or more of the selected liquid flow passages;
(ii) distribute the liquid from the at least one liquid source to at least one of the liquid flow passages while bypassing at least one of the liquid flow passages;
(iii) control the temperature of the liquid distributed to the selected liquid flow passages;
(iv) control the flow rate of the liquid distributed to the selected liquid flow passages; and/or
(v) control the direction of flow of the liquid through the selected liquid flow passages.

22. The substrate support of claim 20, wherein the liquid flow passages are concentrically arranged in the body.

23. The substrate support of claim 20, wherein the at least one liquid source comprises at least one chiller and/or heat exchanger operable to control the temperature of the liquid.

24. The substrate support of claim 20, further comprising at least one thermal break which thermally isolates at least two liquid flow passages from each other.

25. The substrate support of claim 20, further comprising a heat transfer gas supply system operable to supply heat transfer gas between the support surface and the substrate.

26. The substrate support of claim 20, which includes an electrostatic chuck.

27. A plasma processing apparatus comprising the substrate support according to claim 20.

28. A method of thermally controlling a substrate support in a plasma processing apparatus, comprising:
placing a substrate on the support surface of the substrate support according to claim 20 in a reaction chamber of a plasma processing apparatus;
introducing a process gas into the reaction chamber;
generating a plasma from the process gas in the reaction chamber;
processing the substrate; and
selectively distributing liquid from at least one liquid source to at least the first liquid flow passage via the first inlet and/or the second liquid flow passage via the second inlet so as to control the temperature at one or more portions of the support surface.

29. A method of processing a semiconductor substrate in a plasma processing apparatus, comprising:
supporting a semiconductor substrate on a support surface of a support body in a reaction chamber of a plasma processing apparatus;
circulating liquid in a first liquid flow passage extending through a first portion of the support body so as to provide temperature control of the first portion of the support surface; and
circulating liquid in a second liquid flow passage extending through a second portion of the support body so as to provide temperature control of the second portion of the support surface;
wherein the liquid is circulated in the first liquid flow passage and second liquid flow passage by supplying liquid to a first inlet in fluid communication with the first liquid flow passage, flowing liquid out of a first outlet in fluid communication with the first liquid flow passage, supplying liquid to a second inlet in fluid communication with the second liquid flow passage, and flowing liquid out of a second outlet in fluid communication with the second liquid flow passage.

30. The method of claim 29, further comprising:
flowing liquid through a first supply line in fluid communication with the first inlet;
flowing liquid through a second supply line in fluid communication with the second inlet;
flowing liquid through a first return line in fluid communication with the first outlet; and
flowing liquid through a second return line in fluid communication with the second outlet.

31. The method of claim 30, further comprising:
flowing the liquid from a source of temperature controlled liquid to the first supply line and second supply line;
opening or closing a first valve to control flow of the liquid through the first supply line; and
opening or closing a second valve to control flow of the liquid through the second supply line.

32. The method of claim 31, further comprising:
opening or closing a third valve to control flow of the liquid through the first return line; and
opening or closing a fourth valve to control flow of the liquid through the second return line.

33. The method of claim 30, further comprising:
flowing liquid from a first source of temperature controlled liquid to the first supply line;
opening or closing a first valve to control flow of the liquid through the first supply line;
flowing liquid from a second source of temperature controlled liquid to the second supply line; and
opening or closing a second valve to control flow of the liquid through the second supply line.

34. The method of claim 33, further comprising using a controller to selectively open and close the first valve and second valve.

35. The method of claim 31, further comprising using a controller to selectively open and close the first valve and second valve.

36. The method of claim 29, wherein:
the support surface is circular in shape;
the first liquid flow passage is parallel to the support surface and extends in a circumferential direction; and
the second liquid flow passage is parallel to the support surface and extends in a circumferential direction, the second liquid flow passage being concentric with the first liquid flow passage;
wherein the liquid is circulated in the same or opposite directions in the first liquid flow passage and the second liquid flow passage.

37. The method of claim 29, wherein:
the support surface is circular in shape;
the first liquid flow passage is parallel to the support surface and extends in a circumferential direction; and
the second liquid flow passage is parallel to the support surface and extends in a circumferential direction, the second liquid flow passage being non-concentric with the first liquid flow passage;
wherein the liquid is circulated in the same or opposite directions in the first liquid flow passage and the second liquid flow passage.

38. The method of claim 29, wherein the support surface comprises an exposed surface of an electrostatic chuck, and the substrate is electrostatically clamped by the electrostatic chuck.

39. The method of claim 29, wherein the support body includes a thermal break between the first liquid flow passage and the second liquid flow passage, the thermal break comprising an open channel sized to control thermal conduction through the support body.

40. The method of claim 29, further comprising:
circulating liquid in a third liquid flow passage extending through a third portion of the body so as to provide temperature control of the third portion of the support surface; and
supplying liquid to a third inlet in fluid communication with the third liquid flow passage.

41. The method of claim 29, further comprising supplying heat transfer gas to at least one gas passage opening on the support surface.

42. The method of claim 30, further comprising:
supplying liquid from a source of temperature controlled liquid;
opening or closing valves including a first valve, a second valve, a third valve and a fourth valve; and
flowing liquid through a common line in fluid communication with the first supply line, second supply line, first return line and second return line,
wherein the common line supplies liquid from a source of temperature controlled liquid to the first supply line and second supply line, the common line receives liquid from the first return line and second return line, the first valve controls flow of the liquid through the first return line, the second valve controls flow of the liquid through the second return line, the third valve controls flow of the liquid through a portion of the common line between the first supply line and first return line, and the fourth valve controls flow of the liquid through a portion of the common line between the second supply line and second return line.

43. The method of claim 30, further comprising:
supplying liquid from a source of temperature controlled liquid;
opening or closing valves including a first valve, a second valve, a third valve, a fourth valve, a fifth valve, and a sixth valve; and
flowing liquid through a first connecting line and a second connecting line in fluid communication with the first supply line, second supply line, first return line, and second return line;
wherein the first supply line and second supply line supply liquid from the source of temperature controlled liquid to the first liquid flow passage and second liquid flow passage, the first connecting line extends between the first supply line and second supply line, the second connecting line extends between the first return line and second return line, the first valve controls flow of the liquid through the first supply line, the second valve controls flow of the liquid through the second supply line, the third valve controls flow of the liquid through the first connecting line, the fourth valve controls flow of the liquid through the first return line, the fifth valve controls flow of the liquid through the second return line, and the sixth valve controls flow of the liquid through the second connecting line.
